(19) United States
(12) Patent Application Publication
(10) Pub. No.: US 2024/0232480 A1
(43) Pub. Date: Jul. 11, 2024

(54) PREDICTION SYSTEM AND METHOD FOR THE SPREAD OF INDOOR CONTAMINATION OF CBR

(71) Applicant: AGENCY FOR DEFENSE DEVELOPMENT, Daejeon (KR)

(72) Inventors: Hyunwoo NAM, Daejeon (KR); Hyeyun KU, Daejeon (KR); Jiyun SEO, Daejeon (KR)

(21) Appl. No.: 18/481,126

(22) Filed: Oct. 4, 2023

(30) Foreign Application Priority Data
Jan. 5, 2023 (KR) 10-2023-0001519

(51) Int. Cl. G06F 30/28

(52) U.S. Cl. CPC G06F 30/28

(57) ABSTRACT

The system for predicting the indoor contamination spread for CBR according to the present invention includes an input information acquisition unit acquiring model input information including at least any one information of information on an indoor space to be modeled, CBR contamination source information, and environmental setting information, a low-fidelity indoor spread modeling unit calculating an averaged contamination concentration in a designed indoor zone by using an indoor spread model for a concentration change rate of the contamination source according to a flow analysis by a pressure difference based on the acquired indoor space information, and a high-fidelity indoor spread modeling unit calculating a contamination concentration for each lattice previously partitioned in a target indoor zone by using a computational fluid dynamics technique from the acquired indoor space information.

### CROSS-REFERENCE TO RELATED APPLICATION

This application claims priority to Korean Patent Application No. 10-2023-0001519 filed on Jan. 5, 2023, and all the benefits accruing therefrom under 35 U.S.C. § 119, the contents of which is incorporated by reference in its entirety.

### BACKGROUND OF THE INVENTION

### 1. Field of the Invention

The present invention relates to a system and a method for predicting indoor spread of a contamination source of CBR (Chemical, Biological and Radiological), and more particularly, to a system and a method for predicting transfer and spread of chemical, biological, and radioactive contaminants in an indoor space by using a low-fidelity CBR spread modeling technique and a computational fluid dynamics (CFD) based high-fidelity CBR spread modeling technique.

### 2. Description of the Related Art

Toxic chemical agents (CWA) used for the purpose of terrorist attacks such as neuropathy and blister agents, and toxic industrial chemicals (TIC) in an industrial complex are colorless and odorless, and in the case of leakage accidents, the leakage accidents can cause massive casualties in a short time. The need for development of a CBR spread modeling technology for preventing the damage and predicting contamination spread is required.

As an example, there a Nuclear, Biological, and Chemical Reporting And Modeling S/W System (hereinafter, referred to as NBC_RAMS) developed by the Defense Research Institute, and there is a HAZARD prediction and assessment capability (HPAC) system which is a substance spread model in the atmosphere developed by the US Defense Threat Reduction Agency (DTRA).

The technology that predicts the proliferation of the CBRN pollution source in the related art conducts air current analysis by utilizing various weather models with given CBRN accidents and weather information as conditions, and a system is configured to calculate a prediction value for each time zone by utilizing a specific diffusion modeling technique with respect to a process of transferring and diffusing target pollutants into a calculation area.

However, the conventional CBR contaminant spread prediction technology is limited to indoor spread, so the conventional CBR contaminant spread prediction technology has a disadvantage in that there is a limit in predicting CBR indoor spread in which a complicated building internal space, and an influence of an air current or weather are restricted.

In addition, there is a case where when discharge source information of an agent is not early secured when CBR warfare or CBR terror occurs. In particular, it will be not easy to accurately secure source information such as the type of a delivery weapon or the type or a delivery amount of the agent in from the viewpoint of a defender who is difficult to recognize an attack type in advance.

In such a situation, there is a need for a system and method that can reasonably predict the development of indoor CBR risk situations.

### SUMMARY OF THE INVENTION

In order to solve the problem in the related art, an object of the present invention is to provide a system and a method for predicting indoor contamination spread of CBR, which can predict CBR contamination spread for an indoor environment because the use of a conventional CBR contamination spread prediction system for predicting contamination spread in an outdoor environment when CBR situation occurs is restricted in various indoor spaces such as subway and indoor stadiums.

Further, in order to solve the problem in the related art, an object of the present invention is to provide a system and a method for predicting a CBR contamination spread degree by using a low-fidelity CBR spread modeling technique based the low of mass conservation and a CFD based high-fidelity CBR spread modeling technique in a background of various indoor spaces defined by a user.

Specific details of other exemplary embodiments are included in “Details for carrying out the invention” and accompanying “drawings”.

Advantages and/or features of the present invention, and a method for achieving the advantages and/or features will become obvious with reference to various exemplary embodiments to be described below in detail together with the accompanying drawings.

However, the present invention is not limited only to a configuration of each exemplary embodiment disclosed below, but may also be implemented in various different forms. The respective exemplary embodiments disclosed in this specification are provided only to complete disclosure of the present invention and to fully provide those skilled in the art to which the present invention pertains with the category of the invention, and the present invention will be defined only by the scope of each claim of the claims.

In order to achieve the object, a system for predicting the indoor contamination spread for CBR according to the present invention includes an input information acquisition unit acquiring model input information including at least any one information of information on an indoor space to be modeled, CBR contamination source information, and environmental setting information, a low-fidelity indoor spread modeling unit calculating an averaged contamination concentration in a designed indoor zone by using an indoor spread model for a concentration change rate of the contamination source according to a flow analysis by a pressure difference based on the acquired indoor space information, and a high-fidelity indoor spread modeling unit calculating a contamination concentration for each lattice previously partitioned in a target indoor zone by using a computational fluid dynamics technique from the acquired indoor space information.

In addition, the input information acquisition unit includes an indoor space information acquisition unit acquiring information on an indoor space to be modeled, and a user input unit in which CBR contamination source information for which the contamination spread is to be predicted and environmental setting information are input.

In addition, the low-fidelity indoor spread modeling unit includes a low-fidelity model generation unit generating a low-fidelity indoor spread model that mathematically models the concentration change rate of the contamination source according to the flow analysis by the pressure difference of the indoor space based on the acquired model input information based on the law of mass conservation, and a low-fidelity pollution concentration calculation unit calculating an average contamination concentration of the contamination source in the designated indoor zone by using the generated low-fidelity indoor spread model.

In addition, the high-fidelity indoor spread modeling unit includes a high-fidelity indoor spread modeling unit generating a high-fidelity indoor spread model by using a large eddy simulation (LES) technique based on the acquired model input information, a lattice generation unit generating the lattice by introducing an immersed boundary method (IBM) into the indoor space, and a high-fidelity pollution concentration calculation unit calculating the pollution concentration for each lattice in the designated zone of the indoor space based on the generated high-fidelity model and the lattice.

In addition, the system for predicting the indoor contamination spread for CBR further includes an operation control unit controlling operations and motions of the model information acquisition unit, the low-fidelity indoor spread modeling unit, and the high-fidelity indoor spread modeling unit, and generating a contamination spread prediction result generated based on the calculated contamination concentration as output information including an image or video; and an output unit displaying the output information generated by the operation control unit.

In addition, the low-fidelity indoor spread modeling unit generates a mathematical model based on the law of mass conservation for a temporal change of the contamination concentration according to the flow analysis by the pressure difference or a final concentration by the unit of the indoor zone according to user designation based on the acquired indoor space information, and calculates an average contamination concentration in the indoor zone by using the generated model.

In addition, the high-fidelity contamination concentration calculation unit calculates the contamination concentration for each lattice in the designated zone of the indoor space based on the generated high-fidelity indoor spread model and the lattice by using a GPU parallel high-speed computation processing technique.

In addition, in order to achieve the object, a method for predicting the indoor contamination spread for CBR according to the present invention includes (a) acquiring, by an input information acquisition unit, model input information including at least any one information of information on an indoor space to be modeled, CBR contamination source information, and environmental setting information; (b) calculating, by a low-fidelity indoor spread modeling unit, an averaged contamination concentration in a designed indoor zone by using an indoor spread model for a concentration change rate of the contamination source according to a flow analysis by a pressure difference based on the acquired indoor space information; and (c) calculating, by a high-fidelity indoor spread modeling unit, a contamination concentration for each lattice that partitions the indoor space by an immersed boundary method (IBM) by using a computational fluid dynamics (CFD) technique from the acquired indoor space information.

Further, step (a) above includes (a1) acquiring, by an indoor space information acquisition unit, the information on the indoor and outdoor spaces to be modeled, and (a2) acquiring, by a user input unit, CBR contamination source information to be predicted and environmental setting information which are input.

In addition, step (b) above includes (b1) generating, by a low-fidelity model generation unit, a low-fidelity indoor spread model that mathematically models the concentration change rate of the contamination source according to the flow analysis by the pressure difference of the indoor space based on the acquired model input information based on the law of mass conservation, and (b2) calculating, by a low-fidelity pollution concentration calculation unit, an average contamination concentration of the contamination source in the designated indoor zone by using the generated low-fidelity model.

In addition, step (c) above includes (c1) generating, by a high-fidelity indoor spread modeling unit, a high-fidelity indoor spread model by using a large eddy simulation (LES) technique based on the acquired model input information, (c2) generating, by a lattice generation unit, the lattice by introducing an immersed boundary method (IBM) into the indoor space, and (c3) calculating, by a high-fidelity pollution concentration calculation unit, the pollution concentration for each lattice in the designated zone of the indoor space based on the generated high-fidelity model and the lattice.

The model input information includes at least any one of user input information, analysis control setting information, and result information generated by the low-fidelity indoor spread modeling unit.

In addition, step (c3) above is a step of calculating, by the high-fidelity contamination concentration calculation unit, the contamination concentration for each lattice in the designated zone of the indoor space based on the generated high-fidelity indoor spread model and the lattice by using a GPU parallel high-speed computation processing technique.

In addition, in order to achieve the object, a method for predicting the indoor contamination spread for CBR according to the present invention includes (a) acquiring, by an input information acquisition unit, model input information including at least any one information of information on an indoor space to be modeled, CBR contamination source information, and environmental setting information; (b) calculating, by a low-fidelity indoor spread modeling unit, an averaged contamination concentration in a designed indoor zone by using an indoor spread model for a concentration change rate of the contamination source according to a flow analysis by a pressure difference based on the acquired indoor space information; (c) calculating, by a high-fidelity indoor spread modeling unit, a contamination concentration for each lattice that partitions the indoor space by an immersed boundary method (IBM) by using a computational fluid dynamics (CFD) technique from the acquired indoor space information; (d) generating, by an operation control unit, a contamination spread prediction result generated by a contamination concentration calculated by at least any one of the low-fidelity indoor spread modeling unit and the high-fidelity indoor spread modeling unit as output information including an image or video; and (e) displaying and outputting, by an output unit, the output information.

Further, in the contamination spread prediction result image, a low-fidelity prediction result zone and a high-fidelity prediction result zone are displayed differently from each other.

In addition, an image of the low-fidelity prediction result zone is represented based on a single averaged concentration value, and an image of the high-fidelity prediction result zone is represented and displayed based on a concentration prediction value for each lattice size.

According to the present invention, as a system and a method for predicting the contamination spread for CBR in an indoor space in order to overcome a limitation of a spread modeling technique limited to an outdoor location, provided are a system and a method which can primarily check a contamination spread zone through a quick computation by using a low-fidelity modeling technique and analyze a contamination degree of an indoor space zone in detail by using a high-fidelity modeling technique.

Further, according to the present invention, provided are a system and a method for predicting indoor and outdoor integrated CBR contamination spread like a case where a CBR accident occurs outdoors and introduced into an indoor space and a case where the CBR accident occurs indoors and introduced into an outdoor space by interlocking with a conventional known outdoor spread modeling system.

### BRIEF DESCRIPTION OF THE DRAWINGS

FIG. 1 is a diagram illustrating a block configuration of a system for predicting the indoor contamination spread for CBR according to an exemplary embodiment of the present invention.

FIG. 2 is a detailed flowchart of a method for predicting the indoor contamination spread for CBR according to an exemplary embodiment of the present invention.

FIG. 3 is a diagram illustrating a flowchart for predicting a contamination spread result for indoor space information and CBR accident information by applying the method for predicting the indoor contamination spread for CBR according to an exemplary embodiment of the present invention.

FIG. 4 is a diagram illustrating a detailed process of low-fidelity indoor contamination spread modeling in the method for predicting the indoor contamination spread for CBR according to an exemplary embodiment of the present invention.

FIG. 5 is a diagram illustrating a prediction result represented by applying the method for predicting the indoor contamination spread for CBR according to an exemplary embodiment of the present invention.

### DETAILED DESCRIPTION OF THE INVENTION

Before describing the present invention in detail, the terms or words used in this specification should not be construed as being unconditionally limited to their ordinary or dictionary meanings, and in order for the inventor of the present invention to describe his/her invention in the best way, concepts of various terms may be appropriately defined and used, and furthermore, the terms or words should be construed as means and concepts which are consistent with a technical idea of the present invention.

That is, the terms used in this specification are only used to describe preferred embodiments of the present invention, and are not used for the purpose of specifically limiting the contents of the present invention, and it should be noted that the terms are defined by considering various possibilities of the present invention.

Further, in this specification, it should be understood that, unless the context clearly indicates otherwise, the expression in the singular may include a plurality of expressions, and similarly, even if it is expressed in plural, it should be understood that the meaning of the singular may be included.

In the case where it is stated throughout this specification that a component “includes” another component, it does not exclude any other component, but further includes any other component unless otherwise indicated.

Furthermore, it should be noted that when it is described that a component “exists in or is connected to” another component, this component may be directly connected or installed in contact with another component, and in inspect to a case where both components are installed spaced apart from each other by a predetermined distance, a third component or means for fixing or connecting the corresponding component to the other component may exist, and the description of the third component or means may be omitted.

On the contrary, when it is described that a component is “directly connected to” or “directly accesses” to another component, it should be understood that the third element or means does not exist.

Similarly, it should be construed that other expressions describing the relationship of the components, that is, expressions such as “between” and “directly between” or “adjacent to” and “directly adjacent to” also have the same purpose.

In addition, it should be noted that if terms such as “one side”, “other side”, “one side”, “other side”, “first”, “second”, etc., are used in this specification, the terms are used to clearly distinguish one component from the other component and a meaning of the corresponding component is not limited used by the terms.

Further, in this specification, if terms related to locations such as “upper”, “lower”, “left”, “right”, etc., are used, it should be understood that the terms indicate a relative location in the drawing with respect to the corresponding component and unless an absolute location is specified for their locations, these location-related terms should not be construed as referring to the absolute location.

Further, in this specification, in specifying the reference numerals for each component of each drawing, the same component has the same reference number even if the component is indicated in different drawings, that is, the same reference number indicates the same component throughout the specification.

In the drawings attached to this specification, a size, a location, a coupling relationship, etc. of each component constituting the present invention may be described while being partially exaggerated, reduced, or omitted for sufficiently clearly delivering the spirit of the present invention, and thus the proportion or scale may not be exact.

Further, hereinafter, in describing the present invention, a detailed description of a configuration determined that may unnecessarily obscure the subject matter of the present invention, for example, a detailed description of a known technology including the prior art may be omitted.

Hereinafter, a preferred exemplary embodiment of the present invention will be described in detail with reference to the accompanying drawings.

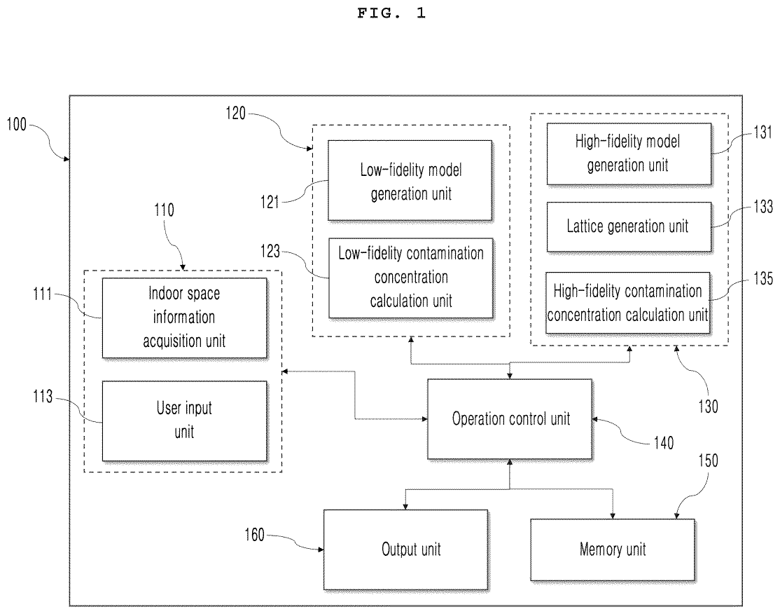

FIG. 1 is a diagram illustrating a block configuration of a system for predicting the indoor contamination spread for CBR according to an exemplary embodiment of the present invention.

As illustrated in FIG. 1, the system 100 for predicting the indoor contamination spread for CBR according to an exemplary embodiment of the present invention may be configured to include an input information acquisition unit 110 acquiring model input information including at least any one information of information on an indoor space to be modeled, CBR contamination source information, and environmental setting information, a low-fidelity indoor spread modeling unit 120 calculating an averaged contamination concentration in a designed indoor zone by using an indoor spread model for a concentration change rate of the contamination source according to a flow analysis by a pressure difference based on the acquired indoor space information, and a high-fidelity indoor spread modeling unit 130 calculating a contamination concentration for each lattice previously partitioned in a target indoor zone by using a computational fluid dynamics technique from the acquired indoor space information.

As such, the system 100 for predicting the indoor contamination spread for CBR according to an exemplary embodiment of the present invention, which relates to a system which may predict CBR contamination spread for an indoor environment provides a system which may effectively and intuitively predict a CBR contamination spread degree by using a low-fidelity CBR spread modeling technique based on the law of mass conservation and a high-fidelity CBR spread modeling technique based on computational fluid dynamics (CFD) in a background of various indoor spaces defined by a user.

Here, the input information acquisition unit 110 may be configured to include an indoor space information acquisition unit 111 and a user input unit 113.

The indoor space information acquisition unit 111 as a component that acquires information on an indoor space to be modeled for which the CBR indoor spread is to be predicted may be configured to select the corresponding space in a space storing predetermined information for the indoor space for which the CBR indoor spread is to be predicted.

The user input unit 113 as a component in which CBR contamination source information for which the contamination spread is to be predicted and environmental setting information are input may be a component in which the user inputs pollution source information which is not limited, but previous known, and environmental setting information including various conditions and settings for modeling.

In addition, as illustrated in FIG. 1, the low-fidelity indoor spread modeling unit 120 may be configured to include a low-fidelity model generation unit 121 and a low-fidelity contamination concentration calculation unit 123.

The low-fidelity model generation unit 121 may be a component that generates a low-fidelity indoor spread model that mathematically models the concentration change rate of the contamination source according to the flow analysis by the pressure difference of the indoor space based on the acquired model input information based on the law of mass conservation.

The low-fidelity pollution concentration calculation unit 123 may be a component that calculates an average contamination concentration of the contamination source in the designated indoor zone by using the generated low-fidelity indoor spread model.

Here, fidelity means a degree indicating how faithfully the corresponding phenomenon or situation may be reproduced in a simulation or modeling, and low-fidelity means a low fidelity for consideration elements such as a situation or an environment for indoor spread prediction, and high-fidelity means a high fidelity.

Further, the low-fidelity indoor spread modeling unit 120 may be a component that generates a mathematical model based on the law of mass conservation for a temporal change of the contamination concentration according to the flow analysis by the pressure difference or a final concentration by the unit of the indoor zone according to user designation based on the acquired indoor space information, and calculates an average contamination concentration in the indoor zone by using the generated model.

In addition, as illustrated in FIG. 1, the high-fidelity indoor spread modeling unit 130 may be configured to include a high-fidelity model generation unit 131, a lattice generation unit 133, and a high-fidelity contamination concentration calculation unit 135.

Here, the high-fidelity indoor spread modeling unit 130 may be a component that generates a high-fidelity indoor spread model by using a large eddy simulation (LES) technique based on the acquired model input information.

Further, the lattice generation unit 133 may be a component that generates the lattice by introducing an immersed boundary method (IBM) into the indoor space.

The high-fidelity contamination concentration calculation unit 135 may be a component that calculates the contamination concentration for each lattice in the designated zone of the indoor space based on the generated high-fidelity indoor spread model and the lattice.

The large eddy simulation (LES) technique as one of the computational fluid dynamics techniques as a simulation technique that simulates a movement of a fluid and an effect thereof with a computer is, in particular, a technique that may simulate turbulence flow with high accuracy.

Meanwhile, in order to more accurately obtain a simulation result for a fluid flow, a lattice (grid/mesh or lattice) for calculation should also be well considered in addition to a numerical analysis model.

A fluid is basically a continuum, but in order to compute the fluid in the computer, the fluid should be discretized to be processed by the computer.

That is, a lattice such as a Go board is created by finely cutting a large space, and each lattice point represents surrounding flow field data, so a normal numerical solution may be acquired only by densely putting the lattice into a part where a flow field is complicatedly changed when creating the lattice.

However, in that a too large computation amount is required if a lot of lattices are necessarily put, the lattice may be easily generated even with a relatively small computation by using the immersed boundary method (IBM) by a technique of generating the lattice by the lattice generation unit 133 of the high-fidelity indoor spread modeling unit 130 applied to an exemplary embodiment of the present invention.

The immersed boundary method as a method initially developed to simulate movement of a heart and a blood flow by Peskin in 1972 has a feature in which a given simulation is executed in a right-angle coordinate lattice and a peculiar process considering an effect of an immersed boundary on a flow is formed.

Since the lattice is very simply generated by using the immersed boundary method (IBM), there is an advantage in that it is relatively easy to develop a computing model of a CBRN fluid flow in the indoor space having a complicated geometric shape or movement boundary.

Further, in that a time and an effort required for preparing for and initializing the simulation may be remarkably reduced because the need for the complicated lattice is removed, the generation of the lattice using the IBM may be very suitable for a complicated turbulence flow of the CBRN fluid diffused in the indoor space, an interaction of the fluid and the structure, and a complex physical simulation.

Further, the high-fidelity contamination concentration calculation unit 135 may be a component that calculates the contamination concentration for each lattice in the designated zone of the indoor space based on the generated high-fidelity indoor spread model and the lattice by using a GPU parallel high-speed computation processing technique.

That is, the system 100 for predicting indoor contamination spread for CBR according to an exemplary embodiment of the present invention may further include a GPU system for processing the contamination concentration for each lattice at a high speed by parallel computation.

In addition, as illustrated in FIG. 1, the system 100 for predicting the indoor contamination spread for CBR according to an exemplary embodiment of the present invention may be configured to further include, jointly with the model information acquisition unit 110, the low-fidelity indoor spread modeling unit 120, and the high-fidelity indoor spread modeling unit 130, an operation control unit 140 that controls operations and motions of the model information acquisition unit 110, the low-fidelity indoor spread modeling unit 120, and the high-fidelity indoor spread modeling unit 130, and generates a contamination spread prediction result generated based on the calculated contamination concentration as output information including an image or video, and an output unit 160 that displays the output information generated by the operation control unit 140.

More specifically, as illustrated in FIG. 1, the system 100 for predicting the indoor contamination spread for CBR according to an exemplary embodiment of the present invention may be configured to include the operation control unit 140, the input information acquisition unit 110 constituted by the indoor space information acquisition unit 111 and the user input unit 113 connected to the operation control unit 140, the low-fidelity indoor spread modeling unit 120, the high-fidelity indoor spread modeling unit 130, a memory unit 150, and the output unit 160.

Here, the indoor space information acquisition unit 111 may acquire indoor space information defined by the user. This may be text file type RAW data including a CAD based building design result or predefined building design information.

Further, the acquired indoor space information may be stored in an internal memory through a preprocessing process in order to perform a CBR spread modeling function.

In addition, the low-fidelity indoor spread modeling unit 120 may include a function of calculating the temporal change or final concentration of the contamination concentration for CBR accident information acquired by the user in the user input unit 113 and the indoor space acquired by the indoor space information acquisition unit 111 by the unit of the indoor zone according to a simplified mathematical model.

In addition, the high-fidelity indoor spread modeling unit 130 may include a function of performing a physical behavior and CBR contaminant concentration change numerical simulation of an indoor air current using the LED and IBM techniques which are the CFD model for the CBR accident information acquired by the user in the user input unit 113 and the indoor space acquired by the indoor space information acquisition unit 111.

Meanwhile, the memory unit 150 may store various data and programs for the motion of the system 100 for predicting the indoor contamination spread for CBR according to an exemplary embodiment of the present invention.

Further, the memory unit 150 may store indoor space information, a CBR contaminant library, and various environmental setting information for predicting the CBR contamination spread.

In addition, the user input unit 113 as a component for receiving contaminant information (initial concentration), external environment information (weather information), and analysis setting and predefinition information to predict the pollution diffusion from the user may include a mechanical input means and a touch type input means.

Meanwhile, pollution source information such as information, a type, and a physical property of a toxic substance to predict the pollution diffusion may be information stored in the memory unit 150. In this case, at least one toxic substance may be selected according to an input of the user through the user input unit 113 and various information related to the selected toxic substance may be selected.

In addition, the output unit 160 may output various data of the system 100 for predicting the indoor contamination spread for CBR according to an exemplary embodiment of the present invention according to the control of the operation control unit 140.

As an example, the output unit 160 outputs the corrected pollution diffusion prediction result as an imaging image to be visually identified by the user.

To this end, the output unit 160 may include at least one display unit capable of displaying image information. Here, the display unit may be implemented as a Cathode Ray Tube (CRT), a Plasma Display Panel (PDP), a Liquid Crystal Display (LCD), a Light Emitting Diode (LED), an Organic Light Emitting Diode (OLED), etc., but is not limited thereto.

Meanwhile, the operation control unit 140 may control an overall motion of the system 100 for predicting the indoor contamination spread for CBR according to an exemplary embodiment of the present invention. For example, the control/operation control unit 110 may control a motion and a motion order of each connected component, and control each connected component based on the information input through the user input unit 113.

Further, the operation control unit 140 may be selected with and receive at least one in a CBR contaminant list prestored for contamination spread prediction through the user input unit.

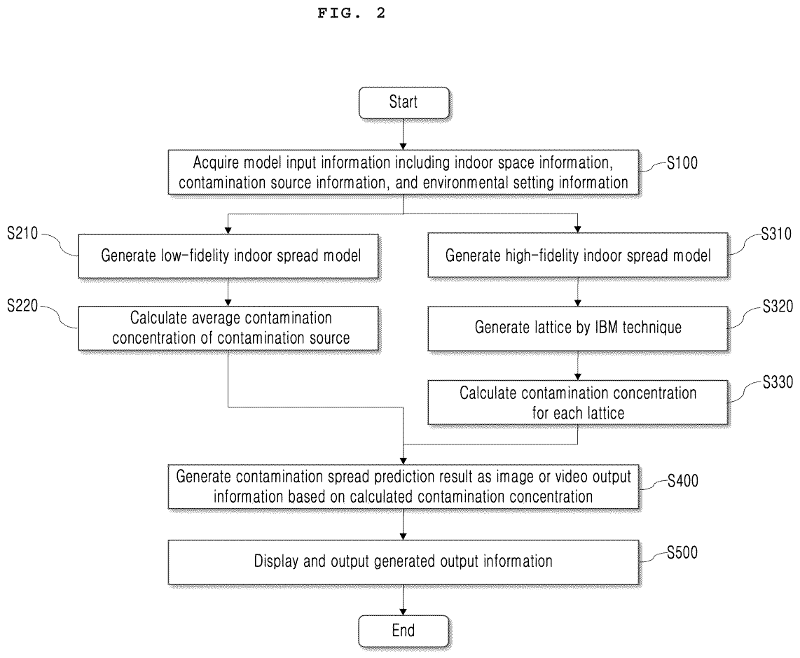

FIG. 2 is a detailed flowchart of a method for predicting the indoor contamination spread for CBR according to an exemplary embodiment of the present invention.

As illustrated in FIG. 2, the method for predicting the indoor contamination spread for CBR according to an exemplary embodiment of the present invention may be configured to include (a) a step S100 of acquiring, by an input information acquisition unit 110, model input information including at least any one information of information on an indoor space to be modeled, CBR contamination source information, and environmental setting information, (b) a step S200 of calculating, by a low-fidelity indoor spread modeling unit 120, an averaged contamination concentration in a designed indoor zone by using an indoor spread model for a concentration change rate of the contamination source according to a flow analysis by a pressure difference based on the acquired indoor space information, (c) a step S300 of calculating, by a high-fidelity indoor spread modeling unit 130, a contamination concentration for each lattice that partitions the indoor space by an immersed boundary method (IBM) technique by using a computational fluid dynamics (CFD) technique from the acquired indoor space information, (d) a step S400 of generating, by an operation control unit 140, a contamination spread prediction result generated based on a contamination concentration calculated by at least any one of the low-fidelity indoor spread modeling unit 120 and the high-fidelity indoor spread modeling unit 130 as output information including an image or video, and (e) a step S400 of displaying and outputting, by an output unit 160, the output information.

Here, (a) step S100 as a step of acquiring the model input information may be configured to include (a1) a step of acquiring, by an indoor space information acquisition unit 111, the information on the indoor space to be modeled, and (a2) a step of acquiring, by a user input unit 113, CBR contamination source information to be predicted and environmental setting information which are input (S110, S120, and S130).

Here, the model input information may include at least any one of user input information, analysis control setting information, and result information generated by the low-fidelity indoor spread modeling unit 120.

Further, step (b) S200 as a step of calculating the averaged contamination concentration by using the low-fidelity indoor spread model may include (b1) a step S210 of generating, by a low-fidelity model generation unit 121, a low-fidelity indoor spread model that mathematically models the concentration change rate of the contamination source according to the flow analysis by the pressure difference of the indoor space based on the acquired model input information based on the law of mass conservation, and (b2) a step S220 of calculating, by a low-fidelity pollution concentration calculation unit 123, an average contamination concentration of the contamination source in the designated indoor zone by using the generated low-fidelity indoor spread model.

Step (c) S300 as a step of calculating the contamination concentration for each lattice by using a high-fidelity indoor spread model may be configured to include (c1) a step S310 of generating, by a high-fidelity model generation unit 131, a high-fidelity indoor spread model by using a large eddy simulation (LES) technique based on the acquired model input information, (c2) a step S320 of generating, by a lattice generation unit 133, the lattice by introducing an immersed boundary method (IBM) into the indoor space, and (c3) a step S330 of calculating, by a high-fidelity contamination concentration calculation unit 135, the contamination concentration for each lattice in the designated zone of the indoor space based on the generated high-fidelity indoor spread model and the lattice.

Here, step (c3) S330 may be a step of calculating by the high-fidelity contamination concentration calculation unit 135, the contamination concentration for each lattice in the designated zone of the indoor space based on the generated high-fidelity indoor spread model and the lattice by using a GPU parallel high-speed computation processing technique.

In addition, step (d) S400 may be a step of generating, by an operation control unit 140, a contamination spread prediction result generated based on a contamination concentration calculated by at least any one of the low-fidelity indoor spread modeling unit 120 and the high-fidelity indoor spread modeling unit 130 as output information including an image or video, and step (e) S500 may be a step of displaying and outputting the generated output information.

Here, in the contamination spread prediction result image, a low-fidelity prediction result zone and a high-fidelity prediction result zone may be displayed differently from each other, and an image of the low-fidelity prediction result zone may be represented based on a single averaged concentration value and an image of the high-fidelity prediction result zone may be represented and displayed based on a concentration prediction value for each lattice size.

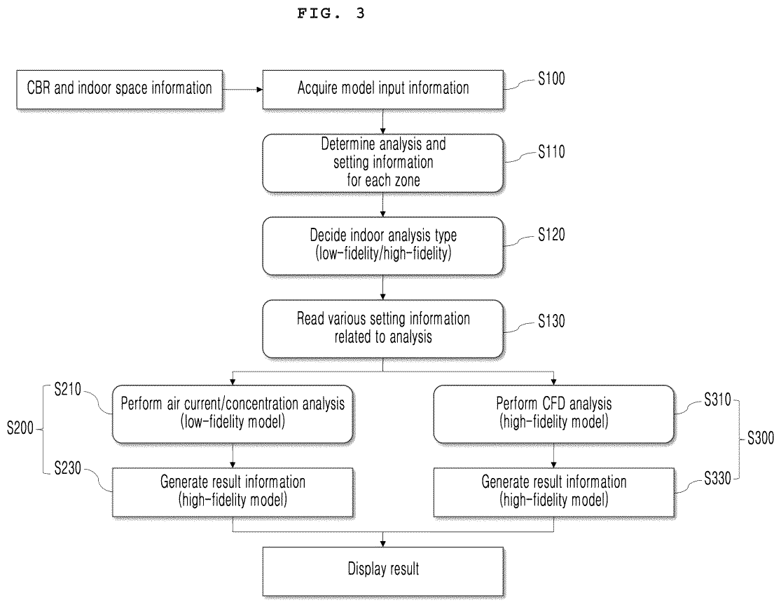

FIG. 3 is a flowchart for predicting a contamination spread result for indoor space information by acquired by the indoor space information acquisition unit 111 and CBR accident information acquired by the user input unit 113.

As illustrated in FIG. 3, information for analyzing contamination spread for each zone is determined with the indoor space information and the CBR accident information acquired by the model input information acquisition unit 110 (S110).

In this case, a function of determining setting information for each zone in the indoor zone and deciding an analysis type (low-fidelity/high-fidelity) is preferentially performed. Further, a function of reading various setting information related to indoor spread analysis according to the analysis type, and storing the read setting information in a memory is included.

As a next process, a contamination spread prediction modeling function is performed an indoor analysis type (low-fidelity/high-fidelity) decided or set by the user (S120) (S200 and S300).

As an example, this is enabled to be designated differently for each indoor zone, that is, it is possible for the user to set a partial section to perform low-fidelity indoor contamination spread prediction modeling (S200) and a partial section to perform high-fidelity indoor contamination spread prediction modeling (S300).

That is, the low-fidelity indoor spread modeling unit 120 may designate a specific zone or section, and perform the low-fidelity contamination spread prediction modeling, by setting or selection of the user through the operation control unit 140 of the system 100 for predicting the indoor contamination spread for CBR according to an exemplary embodiment of the present invention, and the high-fidelity indoor spread modeling unit 130 may perform the high-fidelity contamination spread prediction modeling in a different zone or section.

Further, it is also possible to first perform the low-fidelity contamination spread prediction modeling, and perform the high-fidelity contamination spread prediction modeling stepwise based on a prediction result shown in the low-fidelity contamination spread prediction modeling.

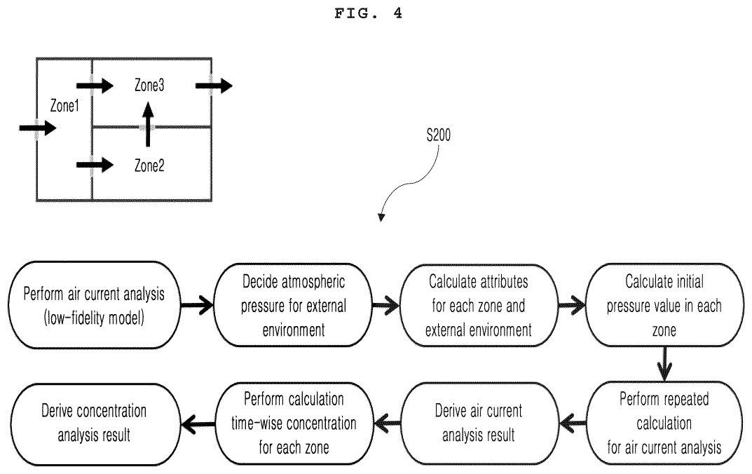

FIG. 4 is a diagram illustrating a detailed process of low-fidelity indoor contamination spread modeling in the method for predicting the indoor contamination spread for CBR according to an exemplary embodiment of the present invention.

That is, FIG. 4 illustrates a flowchart for a low-fidelity indoor contamination spread modeling technique (performing air current analysis) used in the low-fidelity indoor spread modeling unit 120.

As illustrated in FIG. 4, first, external environmental atmospheric pressure for each zone is set. Then, an attribute value for an external environment is calculated by a technique that defines flow movement for each zone based on the law of mass conservation, and initial values for a flow direction and a flow pressure in each zone are calculated and decided.

A flow value is calculated by establishment of a governing equation and repeated calculation for the air current analysis based on the external environment attribute value and the initial pressure value calculated and decided as such.

A calculation in each path assuming a Laminar flow is performed at the time of designating the initial pressure value, and in the case of repetition for the air current analysis, a Newton-Raphson repetition method for deriving a solution satisfying a predetermined condition or converged during a predetermined period may be introduced and applied.

A process of deriving a result of the air current analysis, and calculating and estimating the concentration for each zone by applying a mass conservation equation for the contaminant in each zone is conducted after performing an air current analysis function.

As an example, in respect to the estimation result, a change amount of a contaminant mass per unit time in each zone may be constituted by an entering speed from the outside, a generation speed in the zone, an increase/decrease speed by a chemical reaction in the zone, and an extinction speed in the zone.

In addition, as illustrated in FIGS. 2 and 3, in the high-fidelity indoor contamination spread modeling technique (S300), a computational fluid dynamics (CFD) scheme is used.

The CFD, as a method for numerically analytically approximating a governing equation (Navier-Stokes Equation) in finite number of limited calculation areas, performs a function of discretizing fluid particle aggregates assumed as a continuum to be parallel-computed on the computer by using a GPU system, in particular.

Further, a high-fidelity numerical simulation according to user selection and requirements is driven, and a physical behavior and concentration change numerical simulation of the indoor air current is performed by using a large Eddy simulation (LED) technique by input information, analysis control setting, and by the low-fidelity indoor air current and concentration analysis result.

Further, a function of simplifying a lattice generation computation is applied by using an immersed (virtual) boundary method which applies a virtual boundary to a curve and a moving object in a Cartesian lattice based numerical simulation.

In addition, the operation control unit 140 of the system 100 for predicting the indoor contamination spread for CBR according to an exemplary embodiment of the present invention may specify the CBR contaminant library information and the environmental setting information used in the contamination spread prediction process.

For example, the operation control unit 140 may be selected with at least one of multiple CBR contaminant information (contamination source information) stored in the memory unit 150 in the form of the library through the user input unit 113.

Meanwhile, the operation control unit 140 controls the output unit 160 to aggregate the contamination spread prediction result for each zone, and output the aggregated contamination spread prediction result as the image and the video.

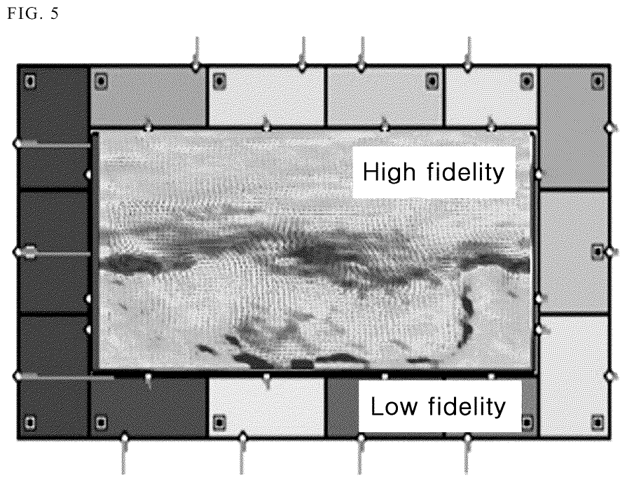

FIG. 5 is a diagram illustrating a prediction result represented by applying the method for predicting the indoor contamination spread for CBR according to an exemplary embodiment of the present invention.

As illustrated in FIG. 5, in the contamination spread prediction result image represented by applying the method for predicting the indoor contamination spread for CBR according to an exemplary embodiment of the present invention, a low-fidelity calculation zone and a high-fidelity calculation zone may be differently displayed, and the low-fidelity calculation zone may be represented by a single averaged concentration value and the high-fidelity calculation zone may represent the concentration prediction value for each lattice size.

Meanwhile, detailed embodiments have been described in describing the present invention and various modifications may be executed without departing from the scope of the present invention. For example, according to the present invention, a spread result for a contamination source including not toxic substance but multiple toxic substances, e.g., multiple chemical gases may also be generated, of course.

The present invention described above can be embodied as computer readable codes on a medium in which a program is recorded. The computer readable medium includes all kinds of recording devices storing data which may be deciphered by a computer system. Examples of the computer readable recording medium include a Hard Disk Drive (HDD), a Solid State Disk (SSD), a Silicon Disk Drive (SDD), a ROM, a RAM, a CD-ROM, a magnetic tape, a floppy disk, an optical data storage device, and the like and further include a device implemented as a type of a carrier wave (e.g., transmission through the Internet). Further, the computer may also include the control/operation unit 110.

Meanwhile, the aforementioned contents can be corrected and modified by those skilled in the art without departing from the essential characteristics of the present invention. Accordingly, the aforementioned detailed description should not be construed as restrictive in all terms and should be exemplarily considered. The scope of the present invention should be determined by rational construing of the appended claims and all modifications within an equivalent scope of the present invention are included in the scope of the present invention.

In the above, although several preferred embodiments of the present invention have been described with some examples, the descriptions of various exemplary embodiments described in the “Specific Content for Carrying Out the Invention” item are merely exemplary, and it will be appreciated by those skilled in the art that the present invention can be variously modified and carried out or equivalent executions to the present invention can be performed from the above description.

In addition, since the present invention can be implemented in various other forms, the present invention is not limited by the above description, and the above description is for the purpose of completing the disclosure of the present invention, and the above description is just provided to completely inform those skilled in the art of the scope of the present invention, and it should be known that the present invention is only defined by each of the claims.

What is claimed is:

1. A system for predicting the indoor contamination spread for CBR (Chemical, Biological and Radiological), the system comprising:
an input information acquisition unit acquiring model input information including at least any one information of information on an indoor space to be modeled, CBR contamination source information, and environmental setting information;
a low-fidelity indoor spread modeling unit calculating an averaged contamination concentration in a designed indoor zone by using an indoor spread model for a concentration change rate of the contamination source according to a flow analysis by a pressure difference based on the acquired indoor space information; and
a high-fidelity indoor spread modeling unit calculating a contamination concentration for each lattice previously partitioned in a target indoor zone by using a computational fluid dynamics technique from the acquired indoor space information.

2. The system for predicting the indoor contamination spread for CBR of claim 1, wherein the input information acquisition unit includes
an indoor space information acquisition unit acquiring information on an indoor space to be modeled, and
a user input unit in which CBR contamination source information for which the contamination spread is to be predicted and environmental setting information are input.

3. The system for predicting the indoor contamination spread for CBR of claim 1, wherein the low-fidelity indoor spread modeling unit includes
a low-fidelity model generation unit generating a low-fidelity indoor spread model that mathematically models the concentration change rate of the contamination source according to the flow analysis by the pressure difference of the indoor space based on the acquired model input information based on the law of mass conservation, and
a low-fidelity pollution concentration calculation unit calculating an average contamination concentration of the contamination source in the designated indoor zone by using the generated low-fidelity indoor spread model.

4. The system for predicting the indoor contamination spread for CBR of claim 1, wherein the high-fidelity indoor spread modeling unit includes
a high-fidelity indoor spread modeling unit generating a high-fidelity indoor spread model by using a large eddy simulation (LES) technique based on the acquired model input information,
a lattice generation unit generating the lattice by introducing an immersed boundary method (IBM) into the indoor space, and
a high-fidelity pollution concentration calculation unit calculating the pollution concentration for each lattice in the designated zone of the indoor space based on the generated high-fidelity model and the lattice.

5. The system for predicting the indoor contamination spread for CBR of claim 1, further comprising:
an operation control unit controlling operations and motions of the model information acquisition unit, the low-fidelity indoor spread modeling unit, and the high-fidelity indoor spread modeling unit, and generating a contamination spread prediction result generated based on the calculated contamination concentration as output information including an image or video; and
an output unit displaying the output information generated by the operation control unit.

6. The system for predicting the indoor contamination spread for CBR of claim 1, wherein the low-fidelity indoor spread modeling unit generates a mathematical model based on the law of mass conservation for a temporal change of the contamination concentration according to the flow analysis by the pressure difference or a final concentration by the unit of the indoor zone according to user designation based on the acquired indoor space information, and calculates an average contamination concentration in the indoor zone by using the generated model.

7. The system for predicting the indoor contamination spread for CBR of claim 4, wherein the high-fidelity contamination concentration calculation unit calculates the contamination concentration for each lattice in the designated zone of the indoor space based on the generated high-fidelity indoor spread model and the lattice by using a GPU parallel high-speed computation processing technique.

8. A method for predicting the indoor contamination spread for CBR, the method comprising:
(a) acquiring, by an input information acquisition unit, model input information including at least any one information of information on an indoor space to be modeled, CBR contamination source information, and environmental setting information;
(b) calculating, by a low-fidelity indoor spread modeling unit, an averaged contamination concentration in a designed indoor zone by using an indoor spread model for a concentration change rate of the contamination source according to a flow analysis by a pressure difference based on the acquired indoor space information; and
(c) calculating, by a high-fidelity indoor spread modeling unit, a contamination concentration for each lattice that partitions the indoor space by an immersed boundary method (IBM) by using a computational fluid dynamics (CFD) technique from the acquired indoor space information.

9. The method for predicting the indoor contamination spread for CBR of claim 8, wherein step (a) above includes
(a1) acquiring, by an indoor space information acquisition unit, the information on the indoor and outdoor spaces to be modeled, and
(a2) acquiring, by a user input unit, CBR contamination source information to be predicted and environmental setting information which are input.

10. The method for predicting the indoor contamination spread for CBR of claim 8, wherein step (b) above includes
(b1) generating, by a low-fidelity model generation unit, a low-fidelity indoor spread model that mathematically models the concentration change rate of the contamination source according to the flow analysis by the pressure difference of the indoor space based on the acquired model input information based on the law of mass conservation, and
(b2) calculating, by a low-fidelity pollution concentration calculation unit, an average contamination concentration of the contamination source in the designated indoor zone by using the generated low-fidelity model.

11. The method for predicting the indoor contamination spread for CBR of claim 8, wherein step (c) above includes
(c1) generating, by a high-fidelity indoor spread modeling unit, a high-fidelity indoor spread model by using a large eddy simulation (LES) technique based on the acquired model input information,
(c2) generating, by a lattice generation unit, the lattice by introducing an immersed boundary method (IBM) into the indoor space, and
(c3) calculating, by a high-fidelity pollution concentration calculation unit, the pollution concentration for each lattice in the designated zone of the indoor space based on the generated high-fidelity model and the lattice.

12. The method for predicting the indoor contamination spread for CBR of claim 11, wherein the model input information includes at least any one of user input information, analysis control setting information, and result information generated by the low-fidelity indoor spread modeling unit.

13. The method for predicting the indoor contamination spread for CBR of claim 11, wherein step (c3) above is a step of calculating, by the high-fidelity contamination concentration calculation unit, the contamination concentration for each lattice in the designated zone of the indoor space based on the generated high-fidelity indoor spread model and the lattice by using a GPU parallel high-speed computation processing technique.

14. A method for predicting the indoor contamination spread for CBR, the method comprising:
(a) acquiring, by an input information acquisition unit, model input information including at least any one information of information on an indoor space to be modeled, CBR contamination source information, and environmental setting information;
(b) calculating, by a low-fidelity indoor spread modeling unit, an averaged contamination concentration in a designed indoor zone by using an indoor spread model for a concentration change rate of the contamination source according to a flow analysis by a pressure difference based on the acquired indoor space information;
(c) calculating, by a high-fidelity indoor spread modeling unit, a contamination concentration for each lattice that partitions the indoor space by an immersed boundary method (IBM) by using a computational fluid dynamics (CFD) technique from the acquired indoor space information;
(d) generating, by an operation control unit, a contamination spread prediction result generated by a contamination concentration calculated by at least any one of the low-fidelity indoor spread modeling unit and the high-fidelity indoor spread modeling unit as output information including an image or video; and
(e) displaying and outputting, by an output unit, the output information.

15. The method for predicting the indoor contamination spread for CBR of claim 14, wherein in the contamination spread prediction result image, a low-fidelity prediction result zone and a high-fidelity prediction result zone are displayed differently from each other.

16. The method for predicting the indoor contamination spread for CBR of claim 15, wherein an image of the low-fidelity prediction result zone is represented based on a single averaged concentration value, and
an image of the high-fidelity prediction result zone is represented and displayed based on a concentration prediction value for each lattice size.
